(19) United States
(12) Patent Application Publication
(10) Pub. No.: US 2012/0205237 A1
(43) Pub. Date: Aug. 16, 2012

(54) METHOD FOR FORMING GAPLESS SEMICONDUCTOR THIN FILM

(76) Inventors: Myung-Hwa Jung, Seoul (KR); Sung-Ik Lee, Seoul (KR); Lee Sunyoung, Seoul (KR)

(21) Appl. No.: 13/346,309

(22) Filed: Jan. 9, 2012

Related U.S. Application Data
(63) Continuation of application No. PCT/KR2010/004882, filed on Jul. 26, 2010.

(30) Foreign Application Priority Data
Jul. 28, 2009 (KR) 10-2009-0068608

(51) Int. Cl. C23C 14/34; C23C 14/08

(52) U.S. Cl. 204/192.15; 204/192.1

(57) ABSTRACT

Provided is a method for forming a gapless semiconductor thin film. The method includes the steps of providing a lead palladium oxide target, arranging the lead palladium oxide target in a vacuum container and providing a substrate, and forming a lead palladium oxide thin film on the substrate using the lead palladium oxide target.

### CROSS-REFERENCE TO RELATED APPLICATIONS

This application is a continuation of and claims priority to PCT/KR2010/004882 filed Jul. 26, 2010, which claims the benefit of and priority to Korean Patent Application No. 10-2009-0068608, filed on Jul. 28, 2009, the entireties of which are hereby incorporated by reference herein.

### BACKGROUND OF THE INVENTION

1. Field of the Invention

The present invention relates to gapless semiconductors and, more particularly, to a method for forming a PbPdO₂ thin film.

2. Description of the Related Art

Thermoelectric devices are used in various applications such as electric power generation using solar energy and electric power generation using body heat, and electric power generation using waste heat and geothermal heat. In addition, thermoelectric devices are used in a future-oriented field as green energy.

A thermoelectric effect was discovered by Thomas Johann Seebeck in 1921. With the discovery of semiconductor materials in 1950s, the thermoelectric effect has been widely applied to industries. Conventionally, Bi₂Te₃ has been used a material causing the thermoelectric effect. The dimensionless thermoelectric figure of merit (ZT) is defined as follows: ZT=σS²/λ (where σ is the electric conductivity, λ is the thermal conductivity, and S is the Seebeck coefficient).

A value of the dimensionless theiinoelectric figure of merit (ZT) of Bi₂Te₃ is close to 1. However, thermoelectric devices using Bi₂Te₃ suffer from disadvantages such as low mechanical strength, difficulty in miniaturization, and vulnerability to humidity.

### SUMMARY OF THE INVENTION

Embodiments of the present invention provide a method for forming a PbPdO₂ thin film with superior thermoelectric characteristics.

According to an embodiment of the present invention, a method for forming a gapless semiconductor thin film may include the steps of providing a lead palladium oxide target; arranging the lead palladium oxide target in a vacuum container and providing a substrate; and forming a lead palladium oxide thin film on the substrate using the lead palladium oxide target.

In an embodiment of the present invention, the step of providing a lead palladium oxide target may include the steps of providing a lead oxide powder; providing a palladium oxide powder; and mixing and sintering the lead oxide powder and the palladium oxide powder. A mixing ratio of the lead oxide powder to the palladium oxide powder may be 1.05:1˜1.2:1.

In an embodiment of the present invention, the sintering of the lead oxide powder and the palladium oxide powder may be performed at a temperature ranging from 650 to 750 degrees centigrade.

In an embodiment of the present invention, the step of forming a lead palladium oxide thin film on the substrate using the lead palladium oxide target may include the steps of heating the substrate; introducing oxygen into the vacuum container; and illuminating a pulse laser to the lead palladium oxide target.

In an embodiment of the present invention, a frequency of the pulse laser may be 3 Hz to 10 Hz.

In an embodiment of the present invention, a pressure of the oxygen introduced into the vacuum container is 100 mTorr to 1 Torr.

In an embodiment of the present invention, a temperature of the substrate may be 700 to 800 degrees centigrade.

In an embodiment of the present invention, the step of forming a lead palladium oxide thin film on the substrate using the lead palladium oxide target may include the steps of heating the substrate introducing oxygen into the vacuum container; and applying a power to the lead palladium oxide target to sputter the lead palladium oxide target.

In an embodiment of the present invention, the method may further include the step of performing a heat treatment for the substrate where the lead palladium oxide thin film is fainted.

In an embodiment of the present invention, the heat treatment for the substrate may be performed in an atmospheric pressure of oxygen ambient and a temperature ranging from 650 to 750 degrees centigrade.

In an embodiment of the present invention, the method may further include the step of cleaning the substrate.

In an embodiment of the present invention, the step of cleaning the substrate may use at least one of acetone, alcohol, and deionized (DI) water.

In an embodiment of the present invention, the substrate may be made of MgO, Si, MgAl₂O₄, GaAs, Al₂O₃ or Si.

In an embodiment of the present invention, the lead palladium oxide thin film may have a single-crystalline or polycrystalline orthorhombic structure.

### BRIEF DESCRIPTION OF THE DRAWINGS

The present invention will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the present invention.

FIGS. 1 and 2 are flowcharts illustrating a method for forming a PbPdO₂ thin film according to an embodiment of the present invention.

FIG. 3 is a graphic diagram illustrating an electric conductivity of the PbPdO₂ thin film formed by the method according to the embodiment of the present invention.

FIG. 4 is a graphic diagram illustrating specific heat of the PbPdO₂ thin film formed by the method according to the embodiment of the present invention.

FIG. 5 is a graphic diagram illustrating Seebeck coefficient (S) of the PbPdO₂ thin film formed by the method according to the embodiment of the present invention.

FIG. 6 is a table diagram illustrating comparison in power factor (S²/ρ) between sodium cobalt oxide and the PbPdO₂ thin film formed by the method according to the embodiment of the present invention.

FIG. 7 illustrates X-ray diffraction (XRD) data of the PbPdO₂ thin film formed by the method according to the embodiment of the present invention.

FIG. 8 illustrates a pulsed laser deposition (PLD) apparatus provided for formation of the PbPdO₂ thin film fowled by the method according to the embodiment of the present invention.

FIG. 9 illustrates a sputter apparatus provided for formation of the PbPdO₂ thin film formed by the method according to another embodiment of the present invention.

### DETAILED DESCRIPTION OF EMBODIMENTS

A gapless semiconductor may be used a magnetic memory device, a Hall device or a thermoelectric device. The magnetic memory device may employ a giant magnetoresistance (GMR) effect. Materials causing the GMR effect require a high spin polarization and a long mean free path. The gapless semiconductor may have a high spin polarization and a long means free path. Hg-based IV-VI group compounds such as HgCdTe and HgCdSe are gapless semiconductors. However, the Hg-based IV-VI group compounds are toxic and may be readily oxidized. Therefore, since oxide-based gapless semiconductors are non-toxic and free from oxidation, they may be used as GMR materials or thermoelectric devices. PbPdO₂ may be a gapless semiconductor. Since a PbPdO₂ thin film may be implemented on a substrate as an element, it may be applied to various fields.

Preferred embodiments of the present invention will now be described more fully hereinafter with reference to the accompanying drawings, in which preferred embodiments of the present invention are shown. However, the present invention may be embodied in many different forms and should not be construed as limited to the embodiments set forth herein. Rather, these embodiments are provided so that this disclosure will be thorough and complete, and will fully convey the scope of the present invention to those skilled in the art. In the drawings, elements are exaggerated for clarity. Like numbers refer to like elements throughout.

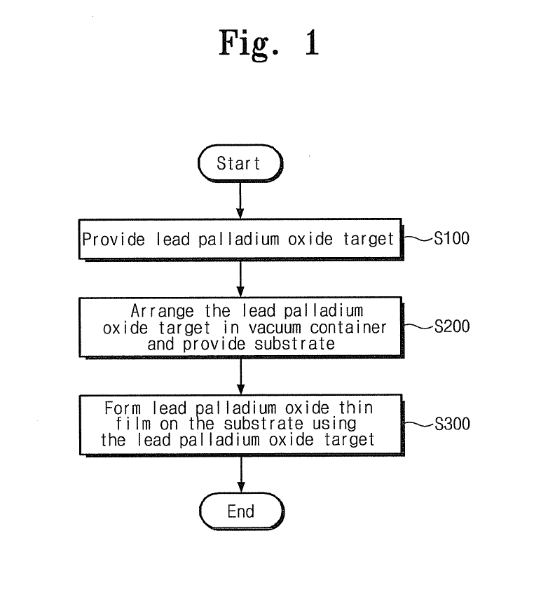

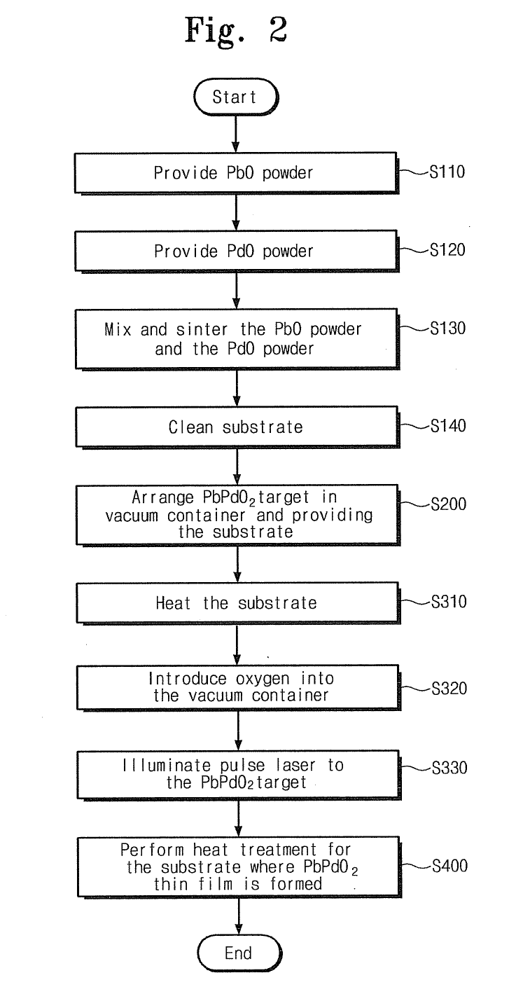

FIGS. 1 and 2 are flowcharts illustrating a method for forming a PbPdO₂ thin film according to an embodiment of the present invention.

Referring to FIGS. 1 and 2, the method for forming a PbPdO₂ thin film includes the steps of providing a PbPdO₂ target (S100), arranging the PbPdO₂ target in a vacuum container and providing a substrate (S200), and forming a PbPdO₂ thin film on the substrate using the PbPdO₂ target (S300).

The step of providing a PbPdO₂ target (S300) includes providing a lead oxide (PbO) powder (S110), providing a palladium oxide (PdO) powder (S120), and mixing and sintering the PbO power and the PdO power (S130). The PbO powder and the PdO powder may have a high purity over 99.99 percent. The sintering of the PbO power and the PdO power may be performed at a temperature ranging from 650 to 750 degrees centigrade. A mole mixing ratio of the PbO powder to the PdO powder may be 1.05:1˜1.2.1. It may take about 12 hours to perform the sintering. The mole mixing ratio of the PbO powder may be dependent on the sintering temperature and the sintering time. The higher mole mixing ratio of the PbO powder may result from high volatility. The sintered PbPdO₂ target may be re-ground to a powder. The ground PbPdO₂ may be re-sintered. The sintering and the grinding may be repeated three times or more. The PbPdO₂ target may be an amorphous or polycrystalline structure.

The vacuum container may include a target holder for holding the PbPdO₂ target. The vacuum container may include a substrate holder for holding the substrate. The substrate may include a substrate heater. The substrate may be made of MgO, Si, MgAl₂O₄, GaAs, Al₂O₃ or Si. The substrate may be sequentially cleaned with acetone, alcohol, and deionized (DI) water. The vacuum container may include a fluid inlet unit for introducing fluid and a fluid exhaust unit for exhausting the fluid. The vacuum container may be exhausted to a base pressure by the fluid exhaust unit. The PbPdO₂ target and the substrate may be disposed opposite to each other. The base pressure may be less than 10⁻⁷ Torr.

The substrate may be heated (S310). The heating of the substrate may be performed by the substrate heater mounted on the substrate holder. A temperature of the substrate may be 700 to 800 degrees centigrade.

Oxygen may be introduced into the vacuum container (S320). A pressure of the oxygen introduced into the vacuum container may be 100 mTorr to 1 Torr. The pressure of the oxygen may change a composition ratio of the deposited PbPdO₂. The oxygen may serve to perform an oxygen supplementation function by means of evaporability of PbO. The vacuum container may contain another inert gas or a reactive gas other than the oxygen.

A pulse laser may be illuminated to the PbPdO₂ target (S330). The pulse laser illuminated to the PbPdO₂ target may ablate the PbPdO₂. The PbPdO₂ desorbed from the PbPdO₂ target may be deposited on the substrate. By the heat of the substrate, the PbPdO₂ deposited on the substrate may form a PbO/PdO structure in which PbO and PdO layers are alternately stacked. A frequency of the pulse laser may be 3 Hz to 10 Hz. A laser fluence may be 2.6 Jule/cm². The pulse laser may be KrF excimer laser having a wavelength of 248 nm. Beam of the pulse laser may be illuminated to the PbPdO₂ through a mirror and a focusing lens.

A heat treatment may be performed on the substrate where the PbPdO₂ thin film is formed (S400). The heat treatment may be performed in oxygen ambient at an atmospheric pressure and a temperature ranging from 650 to 750 degrees centigrade. Preferably, the heat treatment temperature of the substrate may be equal to the deposition temperate of the PbPO₂ thin film. The PbPdO₂ thin film may be a single-crystalline or polycrystalline orthorhombic structure.

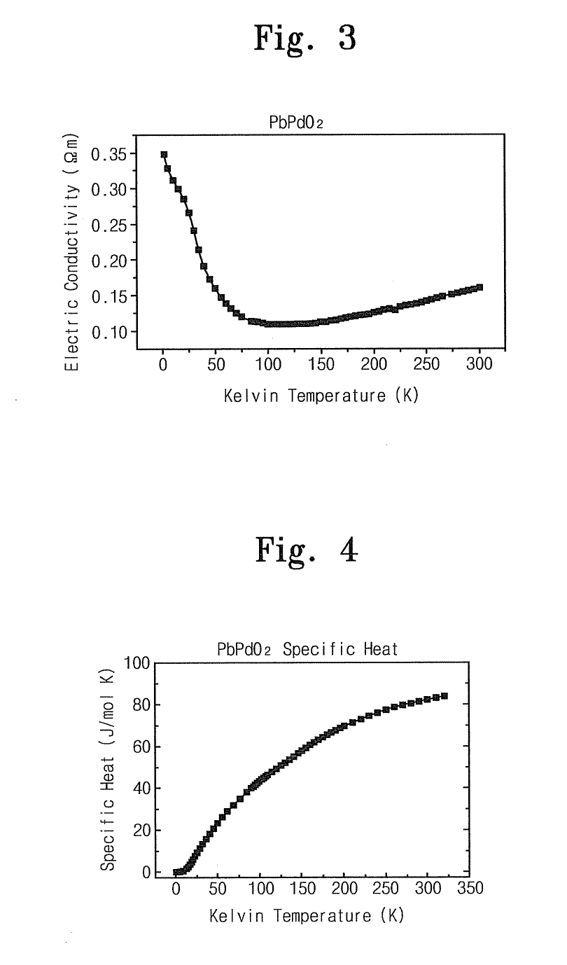

FIG. 3 is a graphic diagram illustrating an electric conductivity of the PbPdO₂ thin film formed by the method according to the embodiment of the present invention.

Referring to FIG. 3, the electric conductivity was measured by a current method using a physical property measuring system (PPMS). The electric conductivity was measured by a four probe method. The electric conductivity exhibited a tendency to gradually increase after rapid decrease with a temperature. The sign of the slope of the electric conductivity varied at a point of 100 K (Kelvin), which may result from metal-insulator transition characteristics.

FIG. 4 a graphic diagram illustrating specific heat of the PbPdO₂ thin film formed by the method according to the embodiment of the present invention.

Referring to FIG. 4, the specific heat was measured using the PPMS. The metal-insulator transition characteristics might be found by measuring the specific heat. However, the specific heat exhibited a characteristic of gradual increase with a temperature. That is, the specific heat did not exhibit the metal-insulator transition characteristics around 100 K (Kelvin), which is the evidence that the PbPdO2 thin film is a gapless semiconductor.

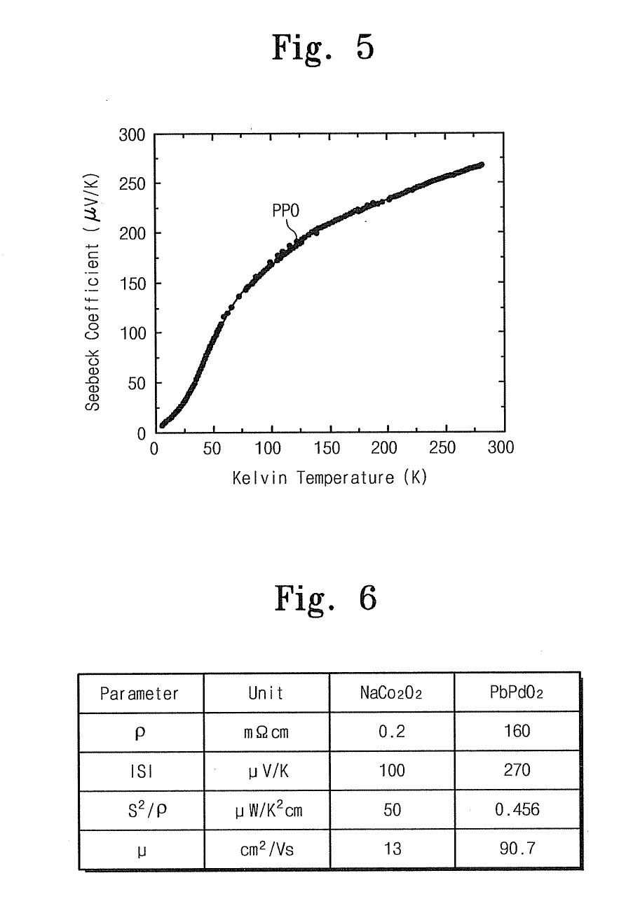

FIG. 5 a graphic diagram illustrating Seebeck coefficient (S) of the PbPdO₂ thin film formed by the method according to the embodiment of the present invention.

Referring to FIG. 5, the Seebeck coefficient (S) was measured using a cryostat system. The Seebeck coefficient (S) exhibited a characteristic of gradual increase with a temperature. The Seebeck coefficient (S) of the PbPdO₂ thin film exhibited a significantly superior characteristic of about 270 μV/K around a room temperature.

FIG. 6 is a table diagram illustrating comparison in power factor (S²/ρ) between sodium cobalt oxide and the PbPdO₂ thin film formed by the method according to the embodiment of the present invention.

Referring to FIG. 6, the Seebeck coefficient (S) of the PbPdO₂ thin film was 270 μV/K at 300 K. A resistivity (ρ) of the PbPdO₂ thin film was 160 mΩcm at 300 K. Accordingly, the power factor (S²/ρ) was 0.456 μW/K²cm. The Seebeck coefficient (S) of the PbPdO₂ thin film is 2.7 times greater than that of NaCo₂O₄. Although a thermal conductivity of the PbPdO₂ thin film was required to calculate dimensionless thermoelectric figure of merit (ZT), it was not measured due to the characteristics of the PbPdO₂ thin film. However, with reference to bulk-type PbPdO₂, the dimensionless thermoelectric figure of merit (ZT) of the PbPdO₂ thin film is expected to be more than 1. A mobility of the PbPdO₂ thin film was calculated by measuring a Hall coefficient. The mobility of the PbPdO₂ thin film was 90.7 cm²/Vsec.

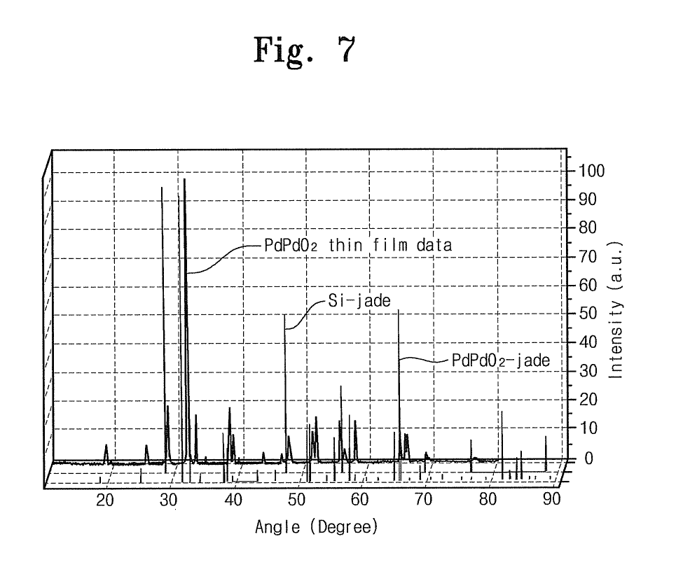

FIG. 7 illustrates X-ray diffraction (XRD) data of the PbPdO₂ thin film formed by the method according to the embodiment of the present invention.

Referring to FIG. 7, it will be understood that the XRD data did not include a contaminant. Peaks of silicon (Si) were observed due to the influence of a silicon substrate. The PbPdO₂ thin film may be single-crystalline or polycrystalline. A crystalline structure of the PbPdO₂ thin film may be an orthorhombic structure. The PbPdO₂ thin film may a structure in which PbO and PdO layers are alternately stacked.

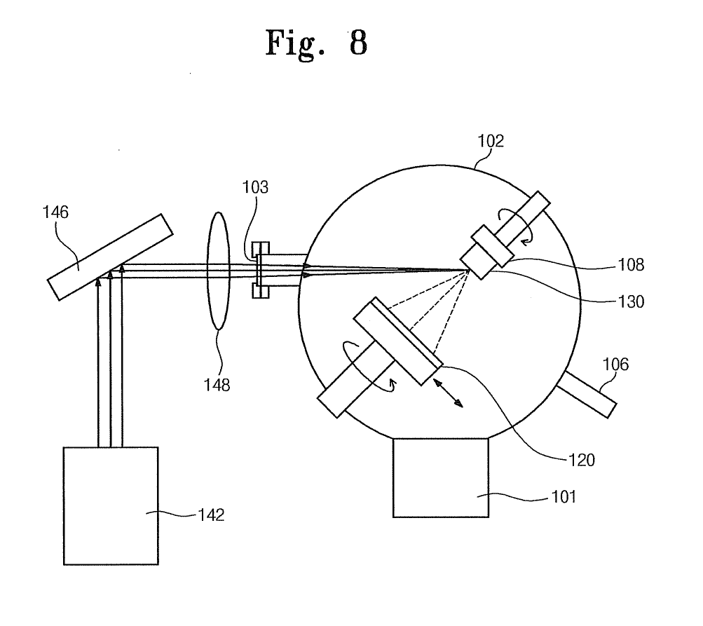

FIG. 8 illustrates a pulsed laser deposition (PLD) apparatus provided for formation of the PbPdO₂ thin film formed by the method according to the embodiment of the present invention.

Referring to FIG. 8, the vacuum container 102 may include a target holder 108 for holding a PbPdO₂ target 130. The target holder 108 is rotatable. The vacuum container 102 may include a substrate holder 104 for holding the substrate 120. The substrate holder 104 may include a substrate heater (not shown). The substrate holder 104 may have a linear or rotary motion. The substrate 120 may be made of MgO, Si, MgAl₂O₄, GaAs, Al₂O₃, or Si. The substrate 120 may be sequentially cleaned with acetone, alcohol, and deionized (DI) water. Heating of the substrate 120 may be performed by the substrate heater. A temperature of the substrate 120 may be 700 to 800 degrees centigrade. The PbPdO₂ target 130 and the substrate 120 may be disposed opposite to each other.

The vacuum container 102 may include a fluid supply unit 106 for introducing gas and a fluid exhaust unit 101 for exhausting the fluid. The vacuum container 102 may be exhausted to a base pressure by the fluid exhaust unit 101. The base pressure may be less than 10⁻⁷ Torr. The fluid supply unit 106 may supply oxygen into the vacuum container 102. A pressure of the oxygen supplied into the vacuum container 102 may be 100 mTorr or 1 Torr. The pressure of the oxygen may change a composition ratio of the PbPdO₂ thin film. The oxygen may serve to perform an oxygen supplementation function by means of evaporability of PbO. The vacuum container 102 may contain another inert gas or a reactive gas other than the oxygen.

Output light of a laser 142 may impinge on a minor 146. The minor 146 may provide reflected light by changing a light path of the output light. The reflected light may be focused through a lens. The focused light may be illuminated to the PbPdO₂ target 130 through a dielectric window 103. The PbPdO₂ target 130 may be ablated to provide a PbPdO₂ thin film onto the substrate 120. The laser 142 may be pulse laser. A frequency of the pulse laser may be 3 Hz to 10 Hz. A laser fluence may be 2.6 Jule/cm². The pulse laser may be KrF excimer laser having a wavelength of 248 nm.

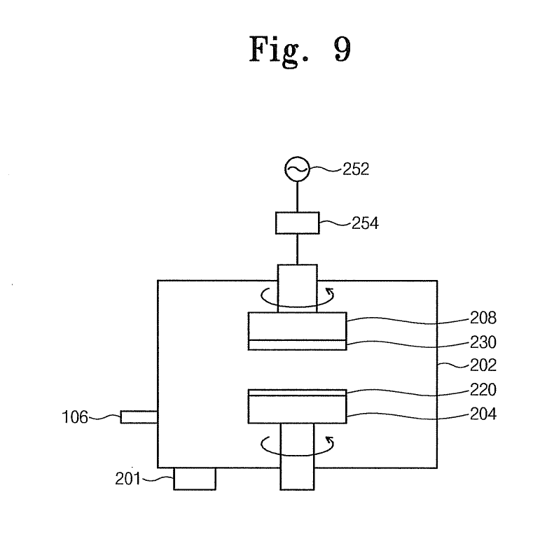

FIG. 9 illustrates a sputter apparatus provided for formation of the PbPdO₂ thin film formed by the method according to another embodiment of the present invention.

Referring to FIG. 9, the vacuum container 202 may include a target holder 208 for holding a PbPdO₂ target 230. An RF power supply 252 or a DC power supply may supply a power to the target holder 130. An impendence matching circuit 254 may be disposed between the RF power supply 252 and the target holder 130.

The vacuum container 202 may include a substrate holder 204 for holding the substrate 220. The substrate holder 204 may include a substrate heater (not shown). The substrate holder 2 may have a linear or rotary motion. The substrate 220 may be made of MgO, Si, MgAl₂O₄, GaAs, Al₂O₃, or Si. The substrate 220 may be sequentially cleaned with acetone, alcohol and deionized (DI) water. Heating of the substrate 220 may be performed by the substrate heater mounted on the substrate holder 204. A temperature of the substrate 220 may be 700 to 800 degrees centigrade. The PbPdO₂ target 230 and the substrate 220 may be disposed opposite to each other.

The vacuum container 202 may include a fluid supply unit 206 for introducing gas and a fluid exhaust unit 201 for exhausting the fluid. The vacuum container 202 may be exhausted to a base pressure by the fluid exhaust unit 201. The base pressure may be less than 10⁻⁷ Torr. The fluid supply unit 206 may supply oxygen into the vacuum container 202. A pressure of the oxygen supplied into the vacuum container 202 may be 100 mTorr or 1 Torr. The pressure of the oxygen may change a composition ratio of the PbPdO₂ thin film. The oxygen may serve to perform an oxygen compensation function by means of evaporability of PbO. The vacuum container 202 may contain another inert gas or a reactive gas other than the oxygen.

The RF power supply or the DC power supply may generate plasma. The plasma may impact against the PdPdO₂ target 230 to sputter the same. The sputtered PdPdO₂ target 230 may provide the PbPdO₂ thin film onto the substrate. The RF power supply or the DC power supply may operate in a pulse mode. A frequency of the RF power supply may be 13.56 MHz.

According to the above-described method of forming a thin film, a PbPdO₂ thin film is provided. The PbPdO₂ thin film may have superior thermoelectric characteristics. The PbPdO₂ thin film may be used in magnetic memory devices, Hall devices, or thermoelectric devices. The PbPdO₂ thin film may be formed in a vacuum container and an oxygen ambient to adjust a composition ratio of PbO.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the present invention.

What is claimed is:

1. A method for forming a gapless semiconductor thin film, comprising the steps of:
providing a lead palladium oxide target;
arranging the lead palladium oxide target in a vacuum container and providing a substrate; and
forming a lead palladium oxide thin film on the substrate using the lead palladium oxide target.

2. The method as set forth in claim 1, wherein the step of providing a lead palladium oxide target comprises the steps of:
providing a lead oxide powder;
providing a palladium oxide powder; and
mixing and sintering the lead oxide powder and the palladium oxide powder,
wherein a mixing ratio of the lead oxide powder to the palladium oxide powder is 1.05:1˜1.2:1.

3. The method as set forth in claim 2, wherein the sintering of the lead oxide powder and the palladium oxide powder is performed at a temperature ranging from 650 to 750 degrees centigrade.

4. The method as set forth in claim 1, wherein the step of forming a lead palladium oxide thin film on the substrate using the lead palladium oxide target comprises the steps of:
heating the substrate;
introducing oxygen into the vacuum container; and
illuminating a pulse laser to the lead palladium oxide target.

5. The method as set forth in claim 4, wherein a frequency of the pulse laser is 3 Hz to 10 Hz.

6. The method as set forth in claim 4, wherein a pressure of the oxygen introduced into the vacuum container is 100 mTorr to 1 Torr.

7. The method as set forth in claim 1, wherein a temperature of the substrate is 700 to 800 degrees centigrade.

8. The method as set forth in claim 1, wherein the step of forming a lead palladium oxide thin film on the substrate using the lead palladium oxide target comprises the steps of:
heating the substrate;
introducing oxygen into the vacuum container; and
applying a power to the lead palladium oxide target to sputter the lead palladium oxide target.

9. The method as set forth in claim 1, further comprising the step of:
performing a heat treatment for the substrate where the lead palladium oxide thin film is formed.

10. The method as set forth in claim 9, wherein the heat treatment for the substrate is performed in an atmospheric pressure of oxygen ambient and a temperature ranging from 650 to 750 degrees centigrade.

11. The method as set forth in claim 1, further comprising the step of:
cleaning the substrate.

12. The method as set forth in claim 11, wherein the step of cleaning the substrate uses at least one of acetone, alcohol, and deionized (DI) water.

13. The method as set forth in claim 1, wherein the substrate is made of MgO, Si, MgAl₂O₄, GaAs, Al₂O₃ or Si.

14. The method as set forth in claim 1, wherein the lead palladium oxide thin film has a single-crystalline or polycrystalline orthorhombic structure.
